(19) United States
(12) Patent Application Publication
(10) Pub. No.: US 2015/0018986 A1
(43) Pub. Date: Jan. 15, 2015

(54) ELECTRICAL SWITCH ASSEMBLY

(71) Applicant: Johnson Electric S.A., Murten (CH)

(72) Inventors: Dirk Weiss, Altena (DE); Udo Balgheim, Hueckeswagen (DE)

(21) Appl. No.: 14/325,729

(22) Filed: Jul. 8, 2014

(30) Foreign Application Priority Data
Jul. 8, 2013 (DE) 102013107177.5

(51) Int. Cl. G05B 15/02; G01R 31/327; H01H 9/16

(52) U.S. Cl. CPC G05B 15/02; H01H 9/161; G01R 31/3277; H01H 2231/024
USPC 700/90

(57) ABSTRACT

An electrical switch assembly is suitable for use in an electrical appliance requiring a descaling procedure after a predetermined number of operating cycles. The switch assembly has a first switch and a second switch. The first switch has a housing, a switch mechanism, contact terminals for the switch mechanism extending from the housing, a microprocessor disposed within the housing and arranged to monitor the status of the switch, an interface for the microprocessor accessible from outside the housing, and an actuator for manually operating the switch mechanism. The second switch provides a signal to the microprocessor indicative of a selected number of operating cycles between descaling procedures, and the microprocessor indicates that descaling is required when the preselected number of operating cycles is reached.

### CROSS REFERENCE TO RELATED APPLICATIONS

This non-provisional patent application claims priority under 35 U.S.C. §119(a) from Patent Application No. 102013107177.5, filed in Germany on Jul. 8, 2013, the entire contents of which are hereby incorporated by reference.

### FIELD OF THE INVENTION

This invention relates to an electrical switch assembly for an appliance and in particular, to a switch assembly including a switch incorporating a microprocessor that monitors the number of operating cycles of the switch.

### BACKGROUND OF THE INVENTION

Published German patent application DE 10 2007 014 174 describes such a switch. This type of switch has proven to be very useful and is frequently used in appliances such as coffee-makers and the like.

The switch is used to control electrical appliances, in particular household appliances such as coffee-making machines. The switch has a number of contact terminals connected to a switch mechanism for selectively varying the electrical connection between the terminals. The switching mechanism includes an activating element biased by a spring in one switching direction and is held in the other direction by a permanent magnet. An electromagnet is used to effect switching of the switch mechanism. The switch is also manually operable. A microprocessor is incorporated into the switch housing to monitor and/or operate the switch in accordance with the requirements of the appliance.

Certain appliances, such as coffee-making machines, require regular decalcification or descaling due to impurities in the water that is used in these machines. The harder the water, the more often descaling is required. However, currently there is not reliable way to monitor when descaling is required and thus often descaling is not done often enough, leading to problems with the machine or the quality of the coffee produced.

### SUMMARY OF THE INVENTION

Hence there is a desire for an electrical switch which monitors the number of operating cycles and indicates when descaling or decalcification is required based on a selectable, predetermined number of operating cycles.

Accordingly, in one aspect thereof, the present invention provides an electrical switch assembly for controlling household electrical appliances, the appliance requiring a descaling procedure after a predetermined number of operating cycles of the appliance, the switch assembly comprising: a first switch comprising: a housing, contact terminals extending from the housing, a microprocessor disposed within the housing and arranged to monitor the status of the first switch, an interface for the microprocessor accessible from outside the housing, an actuator for manually operating the first switch, wherein the microprocessor indicates that descaling is required when the preselected number of operating cycles is reached.

Preferably, a second switch is electrically connected to the microprocessor, the second switch providing a signal to the microprocessor indicative of a selected number of operating cycles between descaling procedures.

Preferably, positions of the second switch indicating selectable numbers of cycles between descaling are selected by movable switching and/or sensing elements.

Preferably, the second switch provides three different signals, indicative of three different numbers of cycles.

Preferably, power is supplied to the second switch through the first switch.

Preferably, the microprocessor is arranged to initiate the descaling procedure when the preselected number of operating cycles is reached, indicating that descaling is in operation.

Preferably, the indication that descaling is required is provided by an optical display which appears until the first switch is reset.

Preferably, the optical display is an LED.

Preferably, the first switch is reset by manually operating the first switch twice within a defined time.

Preferably, the microprocessor is arranged to switch off the first switch after the descaling procedure is finished.

Preferably, the microprocessor counts the number of operating cycles.

Alternatively or in addition, the requirement for descaling is indicated by an acoustic signal.

Through the second switch, it is possible to preset a number of cycles as a limit value for activating the functions stored in the microprocessor. The number of cycles, for example, indicates how often an electrical appliance, such as a coffee-making machine, is switched on. The limit value than indicates the number of cycles at which the microprocessor responds according to how it is programmed. The result is reliable operation, when and how often descaling is required. In order to be able to better manage the different decalcification procedures, the second switch features different positions that each represents a different number of cycles. When the set number of cycles is attained, the switch transmits an optical and/or audial signal to indicate that decalcification is required. In order to keep the construction as simple as possible, it is preferred that the power supply for the second switch is carried out via the main switch itself. It is also recommended that the switch flashes until decalcification is finished. In order to subsequently carry out safe switching off, the microprocessor automatically switches the main switch off after the descaling procedure is finished. Preferably, switching off is carried out by double operation of the main switch within a defined time.

### BRIEF DESCRIPTION OF THE DRAWINGS

A preferred embodiment of the invention will now be described, by way of example only, with reference to figures of the accompanying drawings. In the figures, identical structures, elements or parts that appear in more than one figure are generally labeled with a same reference numeral in all the figures in which they appear. Dimensions of components and features shown in the figures are generally chosen for convenience and clarity of presentation and are not necessarily shown to scale. The figures are listed below.

FIG. 1 is a partial view of an electrical appliance, such as a coffee-making machine, incorporating an electrical switch assembly in accordance with a preferred embodiment of the present invention;

FIG. 2 is a partially exploded view of the switch assembly of FIG. 1;

FIG. 3 is a schematic view of the switch assembly;

FIG. 4 is a further schematic view of the switch assembly; and

FIG. 5 is a perspective view from below of a main switch of the switch assembly.

### DETAILED DESCRIPTION OF THE PREFERRED EMBODIMENTS

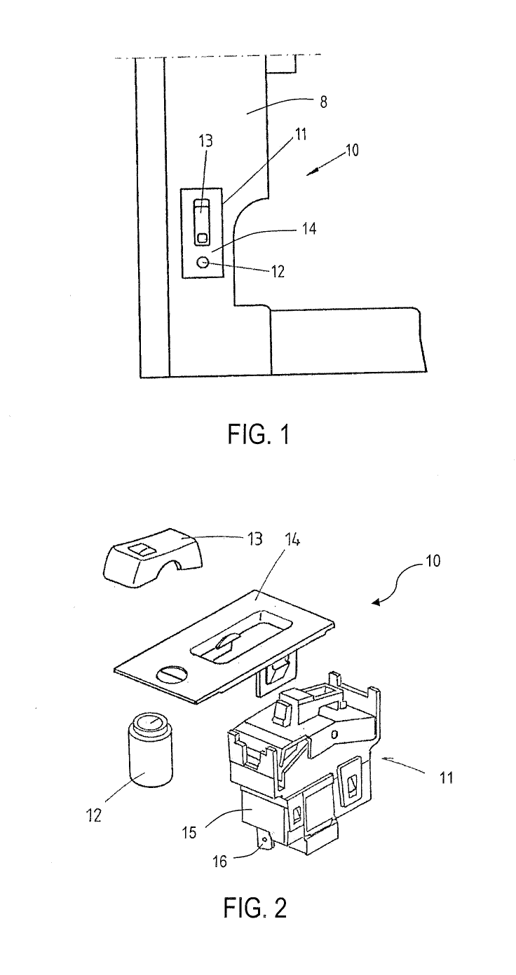

An electrical appliance, in the form of a coffee-making machine 8 is partially illustrated in FIG. 1. An electrical switch assembly 10 is shown mounted on the appliance. The assembly comprises a first or main electrical switch indicated by reference numeral 11 and a second or additional switch indicated by reference numeral 12. A cover 13 is fitted to the main switch 11 and a frame 14 is used to fix the additional switch to the main switch as well as fixing the switch assembly to the appliance. Cover 13 interfaces between a user and an actuating component of switch 11 to allow manual operation of the switch.

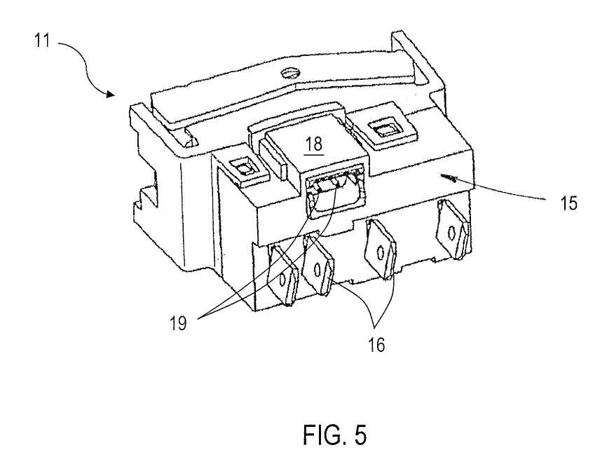

FIG. 2 is a partially exploded view of the switch assembly 10. The main switch 11 has a switch housing 15. FIG. 5 illustrates the main switch 11 from below, showing four contact terminals 16 for the connection of leads to the switch as well as two or more signal terminals for connection of the additional switch 12 for inputting the selected number of cycles required.

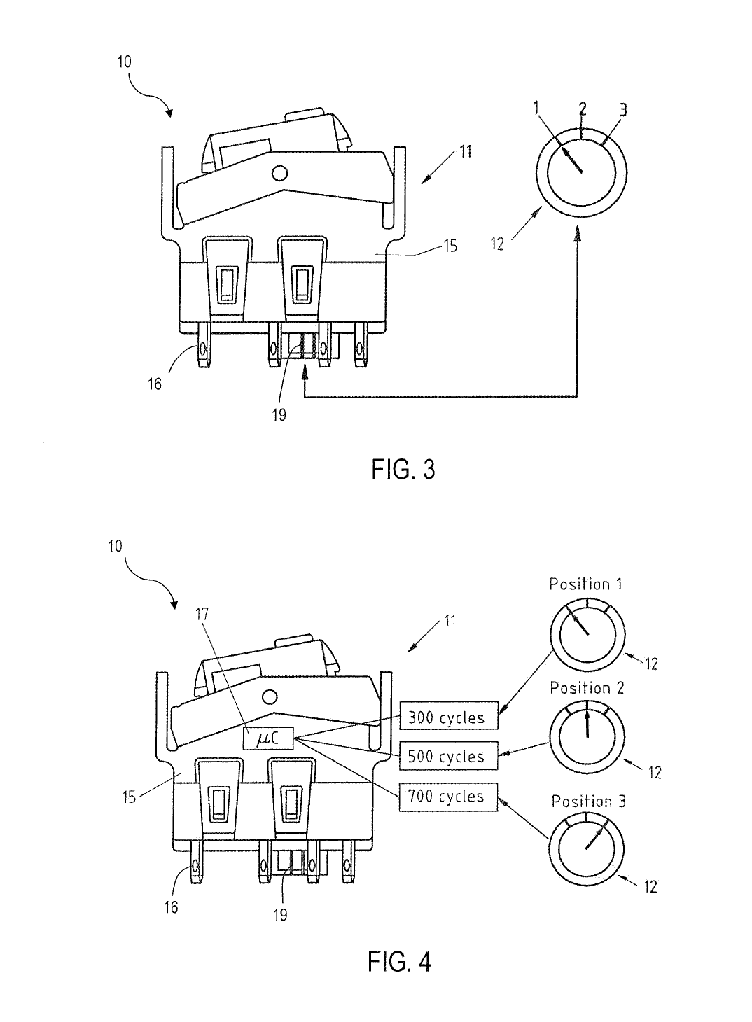

FIG. 3 is a schematic diagram in which a side view of the first switch 11 is illustrated with a signal line connecting the second switch to the first switch.

The second switch 12 is shown in position 1 although able to selected positions 1, 2 or 3. By way of example, position 1 may be selected when using the appliance with hard water, position 2 when use with semi-hard water and position 3 when using soft water.

FIG. 4 is a further schematic diagram in which the positions of the second switch are more clearly explained. Signals are routed from the second switch 12 to the microprocessor 17.

Position 1 is used when hard water is used to make coffee. The microprocessor sets the number of cycles between descaling procedures to, for example, 300 cycles.

Position 2 is used when only medium-soft water is used to make coffee and the microprocessor sets the number of cycles between descaling to, for example, 500 cycles.

Position 3 is used when only soft water is used to make coffee and the microprocessor sets the number of cycles between descaling to, for example, 700 cycles.

Each time the first switch is switched on, a cycle occurs which is monitored or counted by the microprocessor. This number of cycles is subsequently evaluated by the microprocessor. The setting on the second switch remains the same. It is envisaged that the second switch is set to the correct position, depending on the intended use of the machine and is not changed, except when the quality of the water used is changed. The setting of the second switch is not intended to be changed once set, except on exceptional circumstances.

The switch housing 15 is illustrated in FIG. 4, in particular, the external interface 18 is also illustrated.

As soon as the selected number of cycles are attained, a lamp, not illustrated but the light of which is visible through cover 13, starts to flash so that the user can see that descaling is required. After descaling, an arrangement can be carried out by the microprocessor itself, such as automatically turning of the appliance and resetting the cycle count. When again switched on, a new cycle is initiated.

Depending on the complexity of the descaling procedure of the appliance in question, the microprocessor may automatically initiate and complete the descaling procedure, including resetting the cycle count, once the required cycle count is reached

It is expressed here that, of course, only one number of cycles is used by the microprocessor, depending on the setting of the second switch (12).

In order to have a long service life, a LED is used for the flashing lamp to indicate the appropriate status of decalcification.

Instead of or in addition to an optical indication (LED), an acoustic warning can also be emitted. The microprocessor may be in the form of a microcontroller.

In the description and claims of the present application, each of the verbs “comprise”, “include”, “contain” and “have”, and variations thereof, are used in an inclusive sense, to specify the presence of the stated item or feature but do not preclude the presence of additional items or features.

The embodiment described above is provided by way of example only, and various other modifications will be apparent to persons skilled in the field without departing from the scope of the invention as defined by the appended claims.

1. An electrical switch assembly for controlling household electrical appliances, the appliance requiring a descaling procedure after a predetermined number of operating cycles of the appliance, the switch assembly comprising:
a first switch comprising: a housing, contact terminals extending from the housing, a microprocessor disposed within the housing and arranged to monitor the status of the first switch, an interface for the microprocessor accessible from outside the housing, an actuator for manually operating the first switch,
wherein the microprocessor indicates that descaling is required when the preselected number of operating cycles is reached.

2. The assembly of claim 1, further comprising a second switch electrically connected to the microprocessor, the second switch providing a signal to the microprocessor indicative of a selected number of operating cycles between descaling procedures.

3. The assembly of claim 2, wherein the positions of the second switch are selected by movable switching and/or sensing elements.

4. The assembly of claim 2, wherein the second switch provides three different signals, indicative of three different numbers of cycles.

5. The assembly of claim 2, wherein power is supplied to the second switch through the first switch.

6. The assembly of claim 1, wherein the microprocessor is arranged to initiate the descaling procedure when the preselected number of operating cycles is reached, indicating that descaling is in operation.

7. The assembly of claim 1, wherein the indication that descaling is required is provided by an optical display which appears until the first switch is reset.

8. The assembly of claim 7, wherein the optical display is an LED.

9. The assembly of claim 7, wherein the first switch is reset by manually operating the first switch twice within a defined time.

10. The assembly of claim 1, wherein the microprocessor is arranged to switch off the first switch after the descaling procedure is finished.

11. The assembly of claim 1, wherein the microprocessor counts the number of operating cycles.

12. The assembly of claim 1, wherein the requirement for descaling is indicated by an acoustic signal.
